(19) United States
(12) Patent Application Publication
(10) Pub. No.: US 2025/0308723 A1
(43) Pub. Date: Oct. 2, 2025

(54) WIRING BODY AND DISPLAY DEVICE

(71) Applicant: TDK Corporation, Tokyo (JP)

(72) Inventors: Hiroshi SHINGAI, Tokyo (JP); Tomoyuki GOI, Tokyo (JP); Kenichi TEZUKA, Tokyo (JP); Yuusuke IKEMURA, Tokyo (JP); Takahiro TASHIRO, Tokyo (JP)

(73) Assignee: TDK Corporation, Tokyo (JP)

(21) Appl. No.: 19/091,935

(22) Filed: Mar. 27, 2025

(30) Foreign Application Priority Data
Mar. 29, 2024 (JP) 2024-057852

(51) Int. Cl. H01B 1/22; H01B 5/14; H01B 13/00; H10H 29/49

(52) U.S. Cl. CPC H01B 1/22; H01B 5/14; H10H 29/49; H01B 13/0013

(57) ABSTRACT

A wiring body includes a substrate, a mesh-like conductor layer provided on the substrate, and a resin layer covering the conductor layer, in which the resin layer includes a first resin layer and a second resin layer in order from the substrate side, and the conductor layer passes through the first resin layer.

### CROSS-REFERENCE TO RELATED APPLICATION

This application is based upon and claims the benefit of priority from Japanese Patent Application No. 2024-057852, filed on Mar. 29, 2024, the entire contents of which are incorporated herein by reference.

### TECHNICAL FIELD

The present disclosure relates to a wiring body and a display device.

### BACKGROUND

A wiring body has been conventionally known which includes a substrate, a mesh-like conductor pattern provided on the substrate, and a resin layer provided on the substrate (for example, Japanese Unexamined Patent Publication No. 2021-163571). A trench is formed in the resin layer, and an electroconductive line of the conductor pattern is formed in the trench. A lower surface of the electroconductive line is disposed at a position spaced from a main surface of the substrate.

### SUMMARY

A wiring body according to an aspect of the present disclosure includes a substrate, a mesh-like conductor layer provided on the substrate, and a resin layer covering the conductor layer, in which the resin layer includes a first resin layer and a second resin layer in order from the substrate side, and the conductor layer passes through the first resin layer.

A display device according to an aspect of the present disclosure includes the wiring body.

### BRIEF DESCRIPTION OF THE DRAWINGS

FIG. 1 is a plan view illustrating an electroconductive film including a wiring body according to an embodiment;

FIG. 2 is a cross-sectional view taken along the line II-II in FIG. 1;

FIG. 3 is a cross-sectional view illustrating an electroconductive film according to a modification;

FIG. 4 is a cross-sectional view illustrating a display device according to an embodiment;

FIG. 5 is a plan view of an antenna including a wiring body;

FIG. 6 is a cross-sectional view of a wiring body;

FIG. 7 is an enlarged cross-sectional view illustrating a structure in the vicinity of an electroconductive line illustrated in FIG. 6;

FIGS. 8A and 8B are diagrams used for explaining the derivation of Equation (1); and

FIGS. 9A and 9B are graphs used for explaining the derivation of Equation (1).

### DETAILED DESCRIPTION

Here, in the wiring body described above, the electroconductive line is exposed on the surface of the resin layer and, thus, it has been urged to improve the flatness of the surface of the wiring body. It has also been urged to reduce the sheet resistance in the conductor layer of the wiring body.

In view of the above, an object of the present disclosure is to provide a wiring body capable of reducing the sheet resistance while improving the flatness of the wiring body, and a display device.

According to an aspect of the present disclosure, it is possible to provide a wiring body capable of reducing the sheet resistance while improving the flatness of the wiring body, and a display device.

Hereinafter, some embodiments of the present disclosure will be described in detail. However, the present disclosure is not limited to the following embodiments.

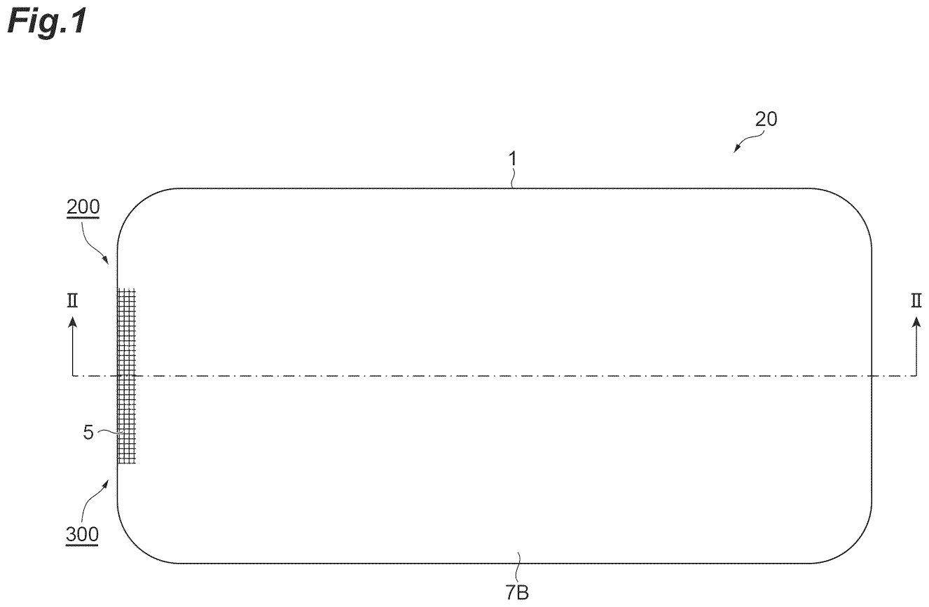

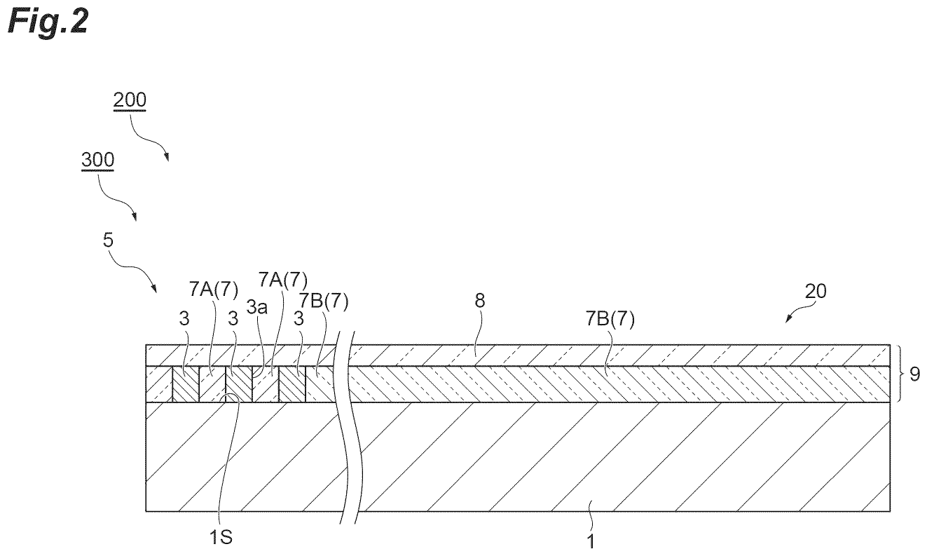

FIG. 1 is a plan view illustrating an electroconductive film including a wiring body 200 according to an embodiment of the present disclosure, and FIG. 2 is a cross-sectional view taken along the line II-II in FIG. 1. An electroconductive film 20 includes an antenna 300, and the antenna 300 includes the wiring body 200. The electroconductive film 20 illustrated in FIGS. 1 and 2 includes a film-like light transmissive substrate 1 (substrate), a conductor layer 5 provided on one main surface 1S of the light transmissive substrate 1, and a resin layer 9 covering the conductor layer 5. The conductor layer 5 has a conductor portion 3 that extends in a direction along the main surface 1S of the light transmissive substrate 1 and has a portion having a pattern including a plurality of openings 3a. The resin layer 9 includes a first resin layer 7 and a second resin layer 8 in this order from the light transmissive substrate 1 side. The first resin layer 7 is provided on one main surface 1S of the light transmissive substrate 1. The first resin layer 7 includes an insulating resin portion 7A filled in the opening 3a of the conductor portion 3, and a light transmissive resin layer 7B provided on the outer peripheral side of the conductor portion 3. The second resin layer 8 is provided so as to cover the first resin layer 7 and the conductor layer 5. In FIG. 2, the conductor layer 5 is illustrated in a deformed manner, and the width of the conductor portion 3 is illustrated in an emphasized manner. The thickness of each layer is also illustrated in a deformed manner. Details of the thickness of each layer will be described later. In the example illustrated in FIG. 1, the conductor layer 5 is formed near one short side of the electroconductive film 20, but the position where the conductor layer 5 is formed is not particularly limited, and the conductor layer 5 may be formed near a long side.

The light transmissive substrate 1 has optical transparency to an extent required when the electroconductive film 20 is incorporated in a display device. Specifically, the total light transmittance of the light transmissive substrate 1 may be 90 to 100%. The light transmissive substrate 1 may have a haze of 0 to 5%.

The light transmissive substrate 1 may be, for example, a transparent resin film, and examples thereof include a film of polyethylene terephthalate (PET), polycarbonate (PC), polyethylene naphthalate (PEN), cycloolefin polymer (COP), or polyimide (PI). Alternatively, the light transmissive substrate 1 may be a glass substrate.

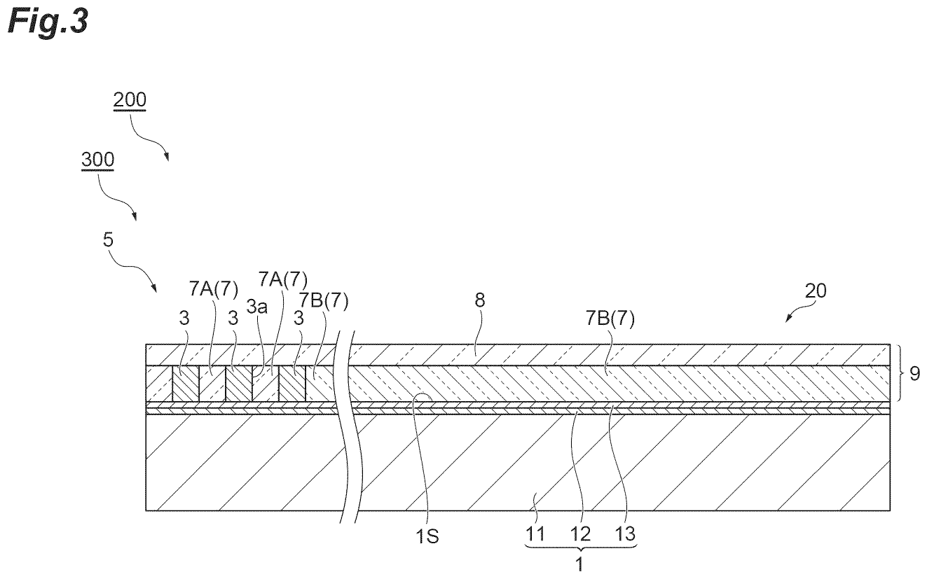

For example, as illustrated in FIG. 3, the light transmissive substrate 1 may be a laminate including a light transmissive support film 11, and an intermediate resin layer 12 and an underlying layer 13 sequentially provided on the support film 11. The support film 11 can be the transparent resin film. The underlying layer 13 is a layer provided in order to form the conductor portion 3 by electroless plating or the like. In a case where the conductor portion 3 is formed by another method, the underlying layer 13 is not necessarily provided. It is not essential that the intermediate resin layer 12 is provided between the support film 11 and the underlying layer 13.

The thickness of the light transmissive substrate 1 or the support film 11 constituting the same may be 10 μm or more, 20 μm or more, or 35 μm or more, and may be 500 μm or less, 200 μm or less, or 100 μm or less.

Providing the intermediate resin layer 12 can improve adhesion between the support film 11 and the underlying layer 13. In a case where the underlying layer 13 is not provided, the intermediate resin layer 12 is provided between the support film 11 and the light transmissive resin layer 7B, so that adhesion between the support film 11 and the light transmissive resin layer 7B can be improved.

The intermediate resin layer 12 may be a layer containing a resin and an inorganic filler. Examples of the resin constituting the intermediate resin layer 12 include an acrylic resin. Examples of the inorganic filler include silica.

The thickness of the intermediate resin layer 12 may be, for example, 5 nm or more, 100 nm or more, or 200 nm or more, and may be 10 μm or less, 5 μm or less, or 2 μm or less.

The underlying layer 13 may be a layer containing a catalyst and a resin. The resin may be a cured product of a curable resin composition. Examples of a curable resin contained in the curable resin composition include an acrylic resin, an amino resin, a cyanate resin, an isocyanate resin, a polyimide resin, an epoxy resin, an oxetane resin, a polyester, an allyl resin, a phenolic resin, a benzoxazine resin, a xylene resin, a ketone resin, a furan resin, a COPNA resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The catalyst contained in the underlying layer 13 may be an electroless plating catalyst. The electroless plating catalyst may be a metal selected from Pd, Cu, Ni, Co, Au, Ag, Pd, Rh, Pt, In, and Sn, or may be Pd. The catalyst may be one kind alone or a combination of two or more kinds. Usually, the catalyst is dispersed in the resin as catalyst particles.

The content of the catalyst in the underlying layer 13 may be 3 mass % or more, 4 mass % or more, or 5 mass % or more, and may be 50 mass % or less, 40 mass % or less, or 25 mass % or less with respect to the total amount of the underlying layer 13.

The thickness of the underlying layer 13 may be 10 nm or more, 20 nm or more, or 30 nm or more, and may be 500 nm or less, 300 nm or less, or 150 nm or less.

The light transmissive substrate 1 may further include a protective layer provided on a main surface of the support film 11 opposite to the light transmissive resin layer 7B and the conductor portion 3. Providing the protective layer prevents the support film 11 from being scratched. The protective layer can be a layer similar to the intermediate resin layer 12. The thickness of the protective layer may be 5 nm or more, 50 nm or more, or 500 nm or more, and may be 10 μm or less, 5 μm or less, or 2 μm or less.

The conductor portion 3 constituting the conductor layer 5 includes a part having a pattern including the openings 3a. The pattern including the openings 3a is a mesh-like pattern that is formed by a plurality of linear portions intersecting each other and includes the plurality of openings 3a regularly arranged. The conductor portion 3 having the mesh-like pattern can favorably function as, for example, a radiation conductor and a feed line of the antenna 300. In addition, the conductor portion 3 may have a planar pattern that functions as a terminal and a ground pad portion and has no openings 3a. The configuration of the pattern of the conductor portion 3 in the conductor layer 5 will be detailed later.

The conductor portion 3 may contain metal. The conductor portion 3 may contain at least one metal selected from copper, nickel, cobalt, palladium, silver, gold, platinum, and tin, or may contain copper. The conductor portion 3 may be metal plating formed by a plating method. The conductor portion 3 may further contain a nonmetallic element such as phosphorus within a range in which appropriate conductivity is maintained.

The conductor portion 3 may be a laminate including a plurality of layers. In addition, the conductor portion 3 may have a blackened layer as a surface layer portion on a side opposite to the light transmissive substrate 1. The blackened layer can contribute to improvement in visibility of a display device in which the electroconductive film is incorporated.

The insulating resin portion 7A is formed of a light transmissive resin and is provided so as to fill the openings 3a of the conductor portion 3.

The light transmissive resin layer 7B is formed of a light transmissive resin. The total light transmittance of the light transmissive resin layer 7B may be 90 to 100%. The light transmissive resin layer 7B may have a haze of 0 to 5%.

The difference between the light transmissive substrate 1 (or the refractive index of the support film constituting the light transmissive substrate 1) and the refractive index of the light transmissive resin layer 7B may be 0.1 or less. As a result, good visibility of a display image is more easily achieved. The refractive index (nd 25) of the light transmissive resin layer 7B may be, for example, 1.0 or more, and may be 1.7 or less, 1.6 or less, or 1.5 or less. The refractive index can be measured by a spectroscopic ellipsometer. In terms of uniformity of the optical path length, the conductor portion 3, the insulating resin portion 7A, and the light transmissive resin layer 7B may have substantially the same thickness.

The resin forming the insulating resin portion 7A and the light transmissive resin layer 7B may be a cured product of a curable resin composition (photocurable resin composition or thermosetting resin composition). The curable resin composition forming the insulating resin portion 7A and/or the light transmissive resin layer 7B includes a curable resin, and examples thereof include an acrylic resin, an amino resin, a cyanate resin, an isocyanate resin, a polyimide resin, an epoxy resin, an oxetane resin, a polyester, an allyl resin, a phenolic resin, a benzoxazine resin, a xylene resin, a ketone resin, a furan resin, a COPNA resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The resin forming the insulating resin portion 7A and the resin forming the light transmissive resin layer 7B may be the same. Since the insulating resin portion 7A and the light transmissive resin layer 7B formed of the same resin have the same refractive index, the uniformity of the optical path length transmitted through the electroconductive film 20 can be further improved. In a case where the resin forming the insulating resin portion 7A and the resin forming the light transmissive resin layer 7B are the same, for example, the insulating resin portion 7A and the light transmissive resin layer 7B can be easily and collectively formed by forming a pattern from one curable resin layer by an imprinting method or the like.

The resin forming the second resin layer 8 may be adopted from the materials mentioned as the materials of the insulating resin portion 7A and the light transmissive resin layer 7B of the first resin layer 7. The same range of optical characteristics such as optical transparency and refractive index may be used for the second resin layer 8 as for the light transmissive resin layer 7B. In addition, the first resin layer 7 and the second resin layer 8 may be made of the same resin material. Alternatively, the first resin layer 7 and the second resin layer 8 may be made of different resin materials.

The electroconductive film 20 can be manufactured, for example, by a method including pattern formation by the imprinting method. An example of a method for manufacturing the electroconductive film 20 includes: preparing the light transmissive substrate 1 including the support film, the intermediate resin layer, and the underlying layer containing the catalyst, the intermediate resin layer, and the underlying layer being provided on one main surface of the support film; forming the curable resin layer on the main surface 1S on the underlying layer side of the light transmissive substrate 1; forming a trench in which the underlying layer is exposed by an imprinting method using a mold having a convex portion; forming the conductor portion 3 filling the trench by an electroless plating method in which metal plating is grown from the underlying layer; and forming the second resin layer 8 so as to cover the first resin layer 7 and the conductor layer 5. The curable resin layer is cured in a state where the mold is pushed into the curable resin layer to thereby form collectively the insulating resin portion 7A having a pattern including an opening with an inverted shape of the convex portion of the mold, and the light transmissive resin layer 7B. The method for forming the insulating resin portion 7A having the pattern including the opening is not limited to the imprinting method, and any method such as photolithography can be applied.

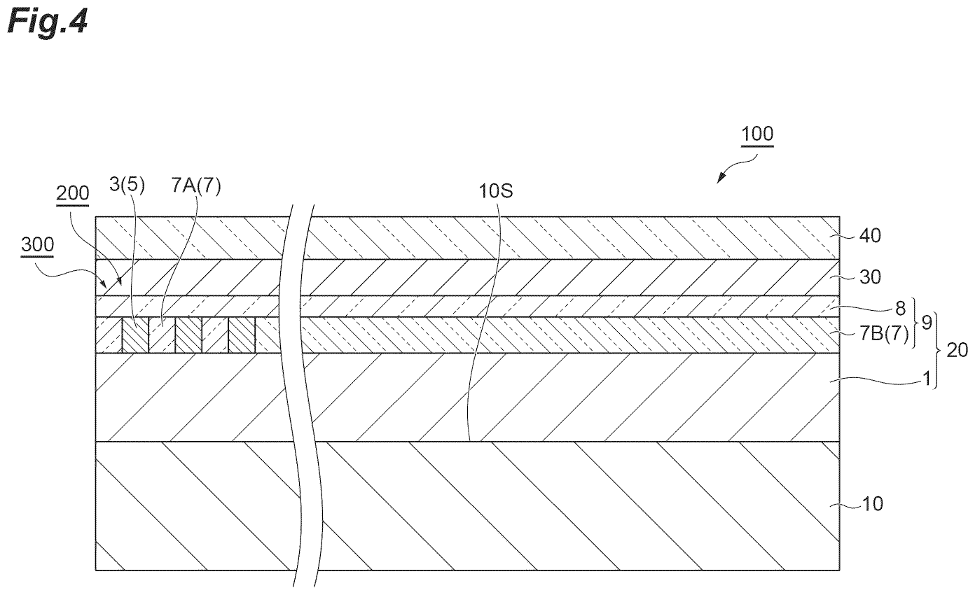

The electroconductive film described above as an example can be incorporated into a display device as, for example, a planar transparent antenna. The display device may be, for example, a liquid crystal display device or an organic EL display device. FIG. 4 is a cross-sectional view illustrating an embodiment of a display device in which an electroconductive film is incorporated. A display device 100 illustrated in FIG. 4 includes an image display unit 10 having an image display region 10S, an electroconductive film 20, a polarizing plate 30, and a cover glass 40. The electroconductive film 20, the polarizing plate 30, and the cover glass 40 are laminated, in this order from the image display unit 10 side, on the image display region 10S side of the image display unit 10. The configuration of the display device is not limited to the form of FIG. 4, and can be appropriately changed as necessary. For example, the polarizing plate 30 may be provided between the image display unit 10 and the electroconductive film 20. The image display unit 10 may be, for example, a liquid crystal display unit. As the polarizing plate 30 and the cover glass 40, those commonly used in a display device can be used. The polarizing plate 30 and the cover glass 40 are not necessarily provided. Light for image display emitted from the image display region 10S of the image display unit 10 passes through a path having a highly uniform optical path length including the electroconductive film 20. This makes it possible to display an image with high uniformity and favorable quality with suppressed moire.

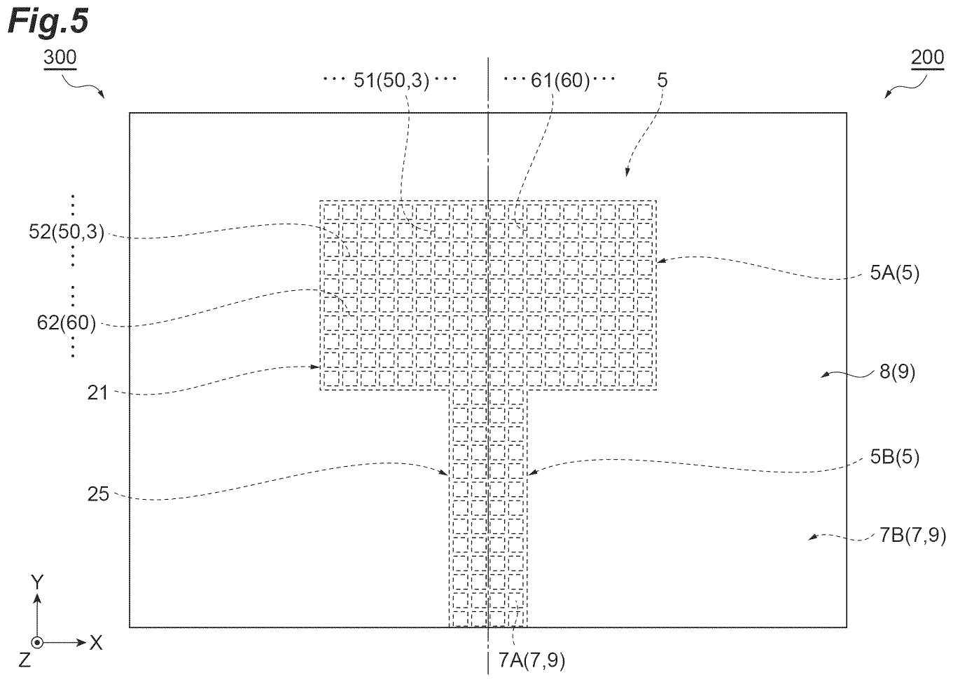

Next, the configurations of the conductor layer 5 and its periphery will be described in more detail with reference to FIG. 5. FIG. 5 is a plan view of the antenna 300 including the wiring body 200. FIG. 5 is an enlarged view of a part of the conductor layer 5. In the following description, it is assumed that XY coordinates are set with respect to a plane parallel to the main surface 1S. The Y-axis direction is a direction along the main surface 1S, and corresponds to a direction orthogonal to a side portion of the electroconductive film 20 in the example illustrated in FIG. 1. The center side of the electroconductive film 20 is defined as a positive side in the Y-axis direction, and the outer peripheral side of the electroconductive film 20 is defined as a negative side in the Y-axis direction. The X-axis direction is a direction orthogonal to the Y-axis direction along the main surface 1S, and corresponds to a direction in which the side portion of the electroconductive film 20 extends in the example illustrated in FIG. 1. One side in which the side portion of the electroconductive film 20 extends is defined as a positive side in the X-axis direction, and the other side is defined as a negative side in the X-axis direction. A direction orthogonal to the X-axis direction and the Y-axis direction is defined as a Z-axis direction. The side on which the resin layer 9 is provided on the light transmissive substrate 1 is defined as a positive side in the Z-axis direction.

As illustrated in FIG. 5, the mesh-like pattern of the conductor layer 5 includes a plurality of first electroconductive lines 51 and a plurality of second electroconductive lines 52. The first electroconductive line 51 is the linear conductor portion 3 extending parallel to the Y-axis direction. The plurality of first electroconductive lines 51 is arranged to be spaced apart from each other in the X-axis direction. The plurality of first electroconductive lines 51 is arranged to be spaced apart at a constant pitch. The second electroconductive line 52 is the linear conductor portion 3 extending parallel to the X-axis direction. The plurality of second electroconductive lines 52 is arranged to be spaced apart from each other in the Y-axis direction. The plurality of second electroconductive lines 52 is arranged to be spaced apart at a constant pitch. The thickness of the electroconductive lines 51 and 52 is not particularly limited, and may be set to, for example, 1 to 3 μm. The pitch of the electroconductive lines 51 and 52 is not particularly limited, and may be set to, for example, 100 to 300 μm. The first electroconductive line 51 does not need to be parallel to the Y-axis direction as long as the first electroconductive line 51 extends in the Y-axis direction, and the second electroconductive line 52 does not need to be parallel to the X-axis direction as long as the second electroconductive line 52 extends in the X-axis direction. In a case where the electroconductive lines 51 and 52 are described without distinguishing therebetween, they may be referred to as an electroconductive line 50. In FIG. 5, the electroconductive lines 51 and 52 are illustrated with hidden lines because they are illustrated via the second resin layer 8.

The conductor layer 5 includes a radiating element portion 5A and a power supply portion 5B. The radiating element portion 5A is a region that radiates a signal as an antenna. The radiating element portion 5A has a rectangular shape having two sides parallel to the Y-axis direction and two sides parallel to the X-axis direction. The power supply portion 5B is a region that feeds power to the radiating element portion 5A. The power supply portion 5B has a belt-like shape extending parallel to the Y-axis direction. The power supply portion 5B is connected to the side of the radiating element portion 5A on the negative side in the Y-axis direction. The power supply portion 5B is connected to a terminal (not illustrated).

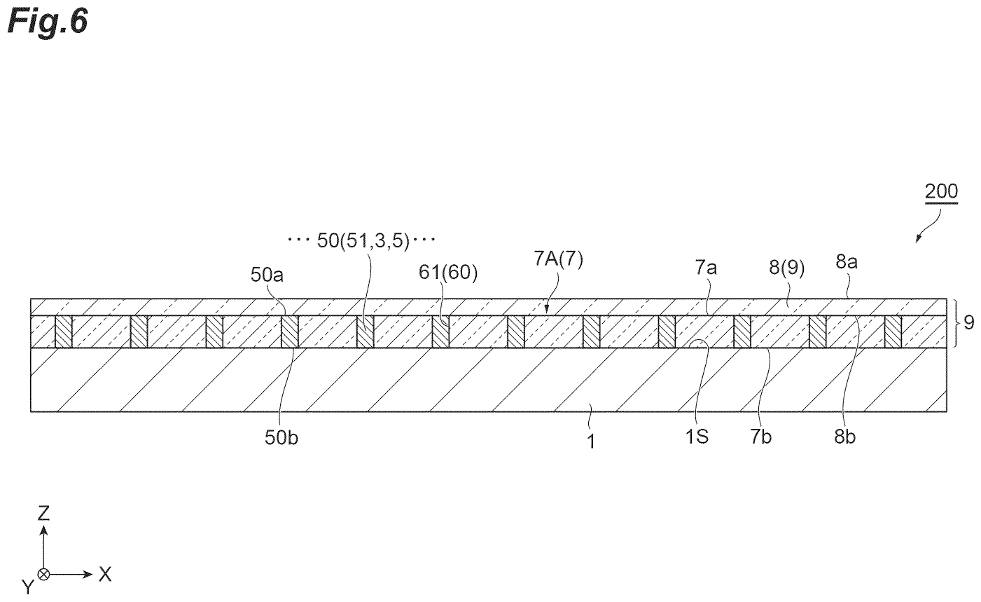

Next, the configurations of the resin layer 9 and the conductor layer 5 will be described in more detail with reference to FIG. 6 in addition to FIG. 5. FIG. 6 is a cross-sectional view of the wiring body 200. In the following description, the words “upper” and “lower” will be used, but the words are not intended to limit the posture of the wiring body 200 during use. In some cases, the positive side in the Z-axis direction is referred to as “upper”, and the negative side in the Z-axis direction is referred to as “lower”. As described above, the first resin layer 7 is provided on the light transmissive substrate 1 as illustrated in FIG. 6. The first resin layer 7 is provided so as to cover the main surface 1S on the positive side in the Z-axis direction of the light transmissive substrate 1. The first resin layer 7 has an upper surface 7a on the positive side in the Z-axis direction and a lower surface 7b on the negative side in the Z-axis direction. The lower surface 7b on the negative side is provided so as to be in contact with the main surface 1S of the light transmissive substrate 1.

In the first resin layer 7, a mesh-like trench 60 passing through the first resin layer 7 in the Z-axis direction (thickness direction) is formed. The mesh-like trench 60 extends from the upper surface 7a on the positive side to the lower surface 7b on the negative side in the Z-axis direction of the first resin layer 7. The electroconductive line 50 of the conductor layer 5 is disposed in the mesh-like trench 60. As illustrated in FIG. 5, the mesh-like trench 60 includes a first trench 61 in which the first electroconductive line 51 is disposed and a second trench 62 in which the second electroconductive line 52 is disposed. The first trenches 61 are arranged at a pitch and width corresponding to the first electroconductive lines 51 described above. The second trenches 62 are arranged at a pitch and width corresponding to the second electroconductive lines 52 described above. That is, the first trenches 61 are linear trenches that extend parallel to the Y-axis direction. The plurality of first trenches 61 is arranged to be spaced apart from each other in the X-axis direction. The plurality of first trenches 61 is arranged to be spaced apart at a constant pitch. The second trenches 62 are linear trenches that extend parallel to the X-axis direction. The plurality of second trenches 62 is arranged to be spaced apart from each other in the Y-axis direction. The plurality of second trenches 62 is arranged to be spaced apart at a constant pitch.

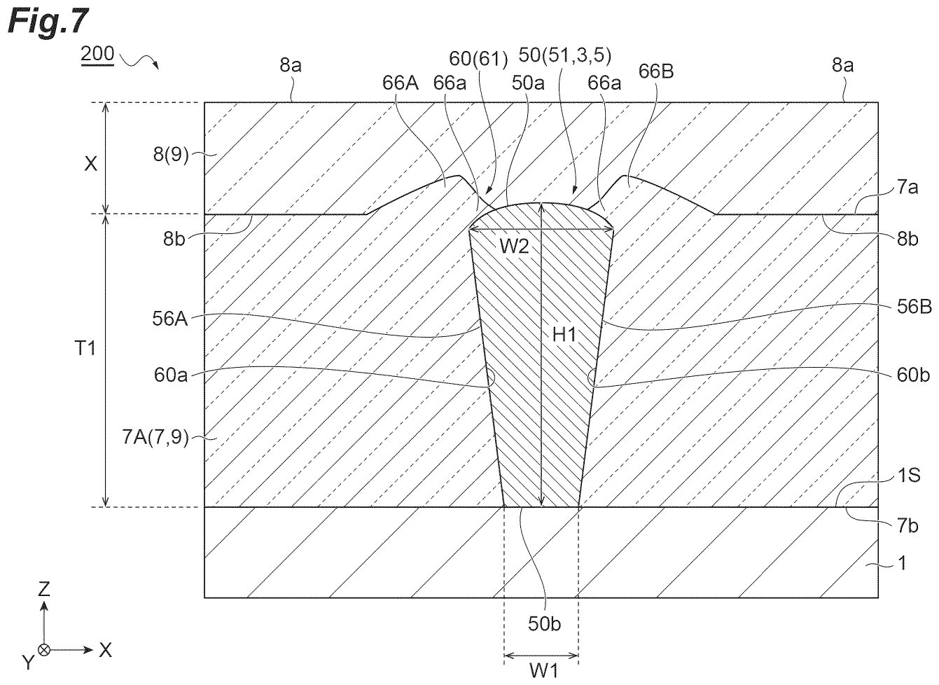

With such a configuration, the conductor layer 5 passes through the first resin layer 7. That is, the electroconductive line 50 extends from the upper surface 7a on the positive side of the first resin layer 7 to the lower surface 7b on the negative side of the first resin layer 7. The electroconductive line 50 has an upper surface 50a extending to the same position as the upper surface 7a of the first resin layer 7 or a position near the upper surface 7a. The electroconductive line 50 has a lower surface 50b that is in contact with the main surface 1S of the light transmissive substrate 1 (see also FIG. 7). The state in which the conductor layer 5 passes through the first resin layer 7 is a state in which the electroconductive line 50 is disposed in the trench 60 of the first resin layer 7 to reach the main surface 1S of the light transmissive substrate 1. Accordingly, the upper surface 50a of the electroconductive line 50 does not need to reach the upper surface 7a of the first resin layer 7, and may be disposed on the negative side in the Z-axis direction with respect to the upper surface 7a.

The second resin layer 8 is provided on the first resin layer 7 and the conductor layer 5. A lower surface 8b of the second resin layer 8 is disposed so as to be in contact with the upper surface 7a of the first resin layer 7 and the upper surface 50a of the electroconductive line 50. At this time, an upper surface 8a of the second resin layer 8 is the uppermost surface of the wiring body 200. As illustrated in FIG. 5, the second resin layer 8 covers not only the entirety of the radiating element portion 5A and the power supply portion 5B of the conductor layer 5 but also the light transmissive resin layer 7B in a region outside the radiating element portion 5A and the power supply portion 5B. In a case where the terminal connected to the power supply portion 5B is formed in the wiring body 200, the terminal is not covered with the second resin layer 8. In this case, the region on the side connected to the terminal of the power supply portion 5B is not covered with the second resin layer 8, either. On the side connected to the terminal of the power supply portion 5B, the region not covered with the second resin layer 8 may be about a half of the power supply portion 5B in the Y-axis direction.

Next, a more detailed configuration of the electroconductive line 50 will be described with reference to FIG. 7. FIG. 7 is an enlarged cross-sectional view illustrating a structure in the vicinity of the electroconductive line 50 illustrated in FIG. 6. In FIG. 7, a cross section of the first electroconductive line 51 extending in the Y-axis direction is illustrated as the electroconductive line 50, and the second electroconductive line 52 extending in the X-axis direction and the periphery thereof also have the same structure. As illustrated in FIG. 7, the electroconductive line 50 has side surfaces 56A and 56B facing each other in the width direction (here, the X-axis direction). The side surface 56A is disposed on one side in the width direction (negative side in the X-axis direction), and the side surface 56B is disposed on the other side in the width direction (positive side in the X-axis direction). As illustrated in the drawing, the upper surface 50a of the electroconductive line 50 may be curved so as to protrude upward. In the meantime, the trench 60 has inner surfaces 60a and 60b facing each other in the width direction. The side surfaces 56A and 56B of the electroconductive line 50 are in surface contact with the inner surfaces 60a and 60b of the trench 60.

The width (dimension in the X-axis direction) of the electroconductive line 50 may increase toward one side in the height direction (positive side in the Z-axis direction). That is, a width dimension W2 in the upper surface 50a of the electroconductive line 50 is greater than a width dimension W1 in the lower surface 50b thereof.

The side surfaces 56A and 56B each have a taper inclined such that a separation distance between the side surfaces 56A and 56B in the X-axis direction increases toward one side in the height direction (positive side in the Z-axis direction). The width of the tapered electroconductive line 50 is defined by the maximum dimension of the width of the electroconductive line 50. A height H1 of the electroconductive line 50 and a thickness T1 (dimension in the height direction) of the first resin layer 7 may be 1.5 to 5.0 μm. In the present embodiment, the height H1 (dimension in the height direction) is greater than the width (dimension in the X-axis direction) of the electroconductive line 50. An aspect ratio (height/width) obtained by dividing the height H1 by the width of the electroconductive line 50 is set to be greater than 1. The aspect ratio may be 2 or more. The width dimension W2 in the upper surface 50a of the electroconductive line 50 may be 110 to 200% greater than the width dimension W1 in the lower surface 50b thereof.

The first resin layer 7 has raised portions 66A and 66B protruding from both sides of the trench 60 to one side (positive side in the Z-axis direction) in the height direction with respect to the upper surface 7a of the first resin layer 7. The raised portions 66A and 66B are portions where a part of the first resin layer 7 is raised so as to be higher on one side in the height direction than the upper surface 7a of the first resin layer 7 near corners between the side surfaces 56A and 56B and the upper surface 50a. The height relationship between the height of the top of the curved surface in the upper surface 50a of the electroconductive line 50 and the upper surface 7a of the first resin layer 7 or the upper ends of the raised portions 66A and 66B is not particularly limited. The raised portions 66A and 66B cover a part on both end sides of the upper surface 50a of the electroconductive line 50 in the width direction with inner peripheral edges 66a.

With the configuration described above, the first resin layer 7 covers the side surfaces 56A and 56B and a part of the upper surface 50a of the electroconductive line 50 constituting the conductor layer 5. Further, the second resin layer 8 covers the first resin layer 7 and the other part of the upper surface 50a of the electroconductive line 50. The other part of the upper surface 50a is a part in the vicinity of the central position in the width direction of the upper surface 50a exposed from the raised portions 66A and 66B of the first resin layer 7. In the upper surface 50a, an area of the part covered with the first resin layer 7 is smaller than an area of the part exposed from the first resin layer 7. Therefore, the area of the second resin layer 8 covering the upper surface 50a of the electroconductive line 50 is greater than the area of the first resin layer 7 covering the upper surface 50a of the electroconductive line 50. When the entire area of the upper surface 50a is 100%, the second resin layer 8 may cover 0 to 80% of the upper surface 50a.

Next, the thickness of the second resin layer 8 will be described. When the thickness of the second resin layer 8 is denoted by X and the resin refractive index of the resin layer 9 (here, the resin refractive index of the second resin layer 8) is denoted by Y, Equation (1) may be satisfied. The right side of Equation (1) is a lower limit value of the thickness X at which the visibility of the electroconductive line 50 does not change when viewed from the upper surface 8a side of the second resin layer 8. That is, even if the thickness X of the second resin layer 8 is set to be greater than the right side of Equation (1), the thickness increases only without improving the visibility. Therefore, the thickness X may be set within a range that satisfies the condition of Equation (1). Note that the lower limit value of the thickness X of the second resin layer 8 is not particularly limited, but may be 0.5 μm or more.

X≤−5.43×Y+11.664 (1)

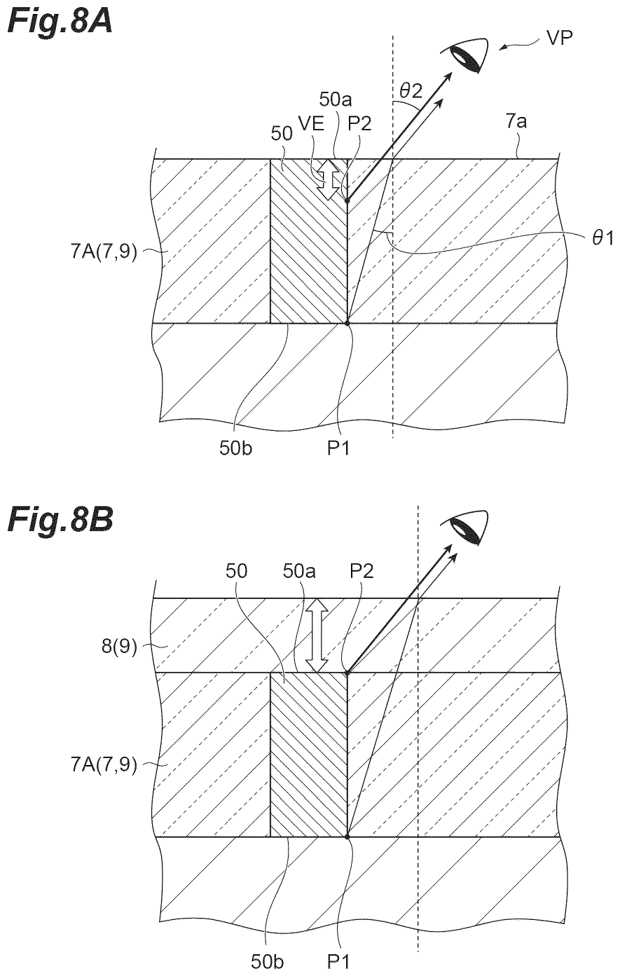

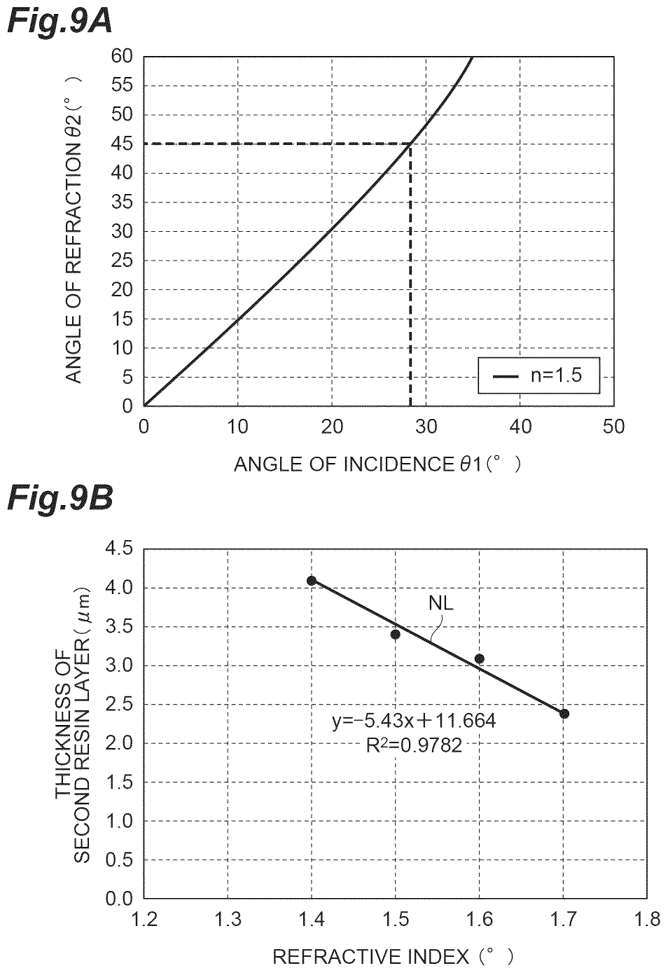

The above Equation (1) will be further described. As illustrated in FIG. 8A, as for a model without the second resin layer 8, the visibility of the electroconductive line 50 when viewed at an angle of 45° will be described. Here, it is assumed that the thickness of the first resin layer 7 (the height of the electroconductive line 50) is 3 μm and the refractive index of the first resin layer 7 is 1.5. As illustrated in FIG. 8A, a position P1 of the lower surface 50b of the electroconductive line 50 is viewed from a viewpoint VP at an angle of 45°. At this time, based on the relationship between an angle of incidence θ1 and an angle of refraction θ2 illustrated in FIG. 9A, the angle of incidence θ1 of light from the position P1 of the lower surface 50b to the viewpoint VP is 28°. Due to the geometric relationship illustrated in FIG. 8A, a virtual image of the position P1 of the lower surface 50b can be seen at a position P2 from the viewpoint VP. Since the position P1 of the lower surface 50b is the lowest position of the electroconductive line 50, the range VE that can be visually recognized from the viewpoint VP is a range of about 1.6 μm that is a range from the upper surface 50a of the electroconductive line 50 to the position P2. As illustrated in FIG. 8B, in a case where the second resin layer 8 is provided, the position P2 at which the virtual image of the position P1 of the lower surface 50b is seen is disposed at a position higher than the position P2 of FIG. 8A. When the thickness of the second resin layer 8 is increased and the position P2 reaches the position of the upper surface 50a of the electroconductive line 50, the electroconductive line 50 cannot be seen from the viewpoint VP. The thickness of the second resin layer 8 at this time is about 3.4 μm. Even if the thickness of the second resin layer 8 is further increased, there is no change in visibility from the viewpoint VP. In this manner, the relationship between the refractive index and the thickness of the second resin layer 8 when there is no change in visibility is plotted in FIG. 9B. An approximate line NL is set for the plotted points. The approximate line NL is “y=−5.43x+11.664”. Equation (1) for the thickness of the second resin layer 8 is derived based on the approximate line NL.

Next, functions and effects of the wiring body 200 and the display device 100 according to the present embodiment will be described.

The wiring body 200 according to the present embodiment includes the light transmissive substrate 1 (substrate), the mesh-like conductor layer 5 provided on the light transmissive substrate 1, and the resin layer 9 covering the conductor layer 5, in which the resin layer 9 includes the first resin layer 7 and the second resin layer 8 in order from the light transmissive substrate 1 side, and the conductor layer 5 passes through the first resin layer 7.

According to the wiring body 200, the mesh-like conductor layer 5 provided on the light transmissive substrate 1 is covered with the resin layer 9 including multiple layers of the first resin layer 7 and the second resin layer 8. This allows the resin layer 9 to absorb a step that can be generated on the surface of the wiring body 200 by the conductor layer 5. Thus, the flatness of the surface of the wiring body 200 can be improved. In the embodiment, the upper surface 8a of the second resin layer 8 is the surface of the wiring body 200. The conductor layer 5 passes through the first resin layer 7 on the light transmissive substrate 1 side. This secures the volume of the conductor while reducing the thickness of the line width of the electroconductive line 50 of the conductor layer 5. Thus, the sheet resistance in the wiring body 200 can be reduced. As described above, the sheet resistance in the wiring body 200 can be reduced while the flatness of the wiring body 200 is increased.

The thickness of the second resin layer 8 may be smaller than the thickness of the first resin layer 7. In this case, by reducing the thickness of the second resin layer 8 that contributes to flattening, it is possible to make the surface of the wiring body 200 flat while preventing an increase in the thickness of the wiring body 200.

The first resin layer 7 and the second resin layer 8 may be made of the same resin material. In this case, it is possible to reduce the influence on the visibility of the conductor layer 5 that can be caused by using the plurality of resin layers.

The aspect ratio obtained by dividing the height of the electroconductive line 50 constituting the conductor layer 5 by the width may be greater than 1. In this case, the electroconductive line 50 is made thinner to prevent an increase in the visibility of the conductor layer 5, and the height of the electroconductive line 50 is secured to ensure the volume of the conductor, so that the sheet resistance can be reduced.

The first resin layer 7 may cover the side surfaces 56A and 56B and a part of the upper surface 50a of the electroconductive line 50 constituting the conductor layer 5, and the second resin layer 8 may cover the first resin layer 7 and the other part of the upper surface 50a of the electroconductive line 50. In this case, the vicinity of the corners between the side surfaces 56A and 56B and the upper surface 50a of the electroconductive line 50 is covered with the first resin layer 7 and, thus, the interface between the side surfaces 56A and 56B of the electroconductive line 50 and the first resin layer 7 and the interface between the upper surface 50a of the electroconductive line 50 and the second resin layer 8 can be prevented from being continuous, which reduces peeling.

The area of the second resin layer 8 covering the upper surface 50a of the electroconductive line 50 may be greater than the area of the first resin layer 7 covering the upper surface 50a of the electroconductive line 50. In this case, the width of the second resin layer 8 can be secured when the second resin layer 8 is filled in a groove (space formed by the raised portion 66A, the raised portion 66B, and the upper surface 50a) formed by the first resin layer 7 on the upper surface 50a. This increases the adhesion between the resin layers due to the anchor effect.

When the thickness of the second resin layer 8 is denoted by X and the resin refractive index of the resin layer 9 is denoted by Y, Equation (1) may be satisfied. In this case, it is possible to prevent an increase in size of the wiring body 200 by increasing the thickness of the second resin layer 8 more than necessary while the thickness of the second resin layer 8 is set to a range in which the influence on the visibility of the conductor layer 5 can be reduced.

X≤−5.43×Y+11.664 (1)

The display device 100 according to an aspect of the present disclosure includes the wiring body 200.

According to the display device 100, functions and effects similar to those of the wiring body 200 described above can be achieved.

The present disclosure is not limited to the embodiment described above.

For example, the shapes of the electroconductive line 50 and the resin layer 9 are not limited to those illustrated in FIG. 7, and can be appropriately changed without departing from the gist of the present disclosure. The height dimension of each portion, the dimensional relationship in the width direction, the relationship of the aspect ratio, and the like are not limited to the above-described embodiment, and can be appropriately changed. For example, a configuration is possible in which the raised portions 66A and 66B are not formed and the entire upper surface 50a is in contact with the second resin layer 8.

### Aspect 1

A wiring body including:
a substrate;
a mesh-like conductor layer provided on the substrate; and
a resin layer covering the conductor layer, in which
the resin layer includes a first resin layer and a second resin layer in order from the substrate side, and
the conductor layer passes through the first resin layer.

### Aspect 2

The wiring body according to aspect 1, in which the second resin layer has a thickness smaller than a thickness of the first resin layer.

### Aspect 3

The wiring body according to aspect 1 or 2, in which the first resin layer and the second resin layer are made of a same resin material.

### Aspect 4

The wiring body according to any one of aspects 1 to 3, in which an aspect ratio obtained by dividing a height dimension of an electroconductive line constituting the conductor layer by a width dimension of the electroconductive line is greater than 1.

### Aspect 5

The wiring body according to any one of aspects 1 to 4, in which the first resin layer covers side surfaces and a part of an upper surface of an electroconductive line constituting the conductor layer, and
the second resin layer covers the first resin layer and another part of the upper surface of the electroconductive line.

### Aspect 6

The wiring body according to aspect 5, in which an area of the second resin layer covering the upper surface of the electroconductive line is greater than an area of the first resin layer covering the upper surface of the electroconductive line.

### Aspect 7

The wiring body according to any one of aspects 1 to 6, in which when a thickness of the second resin layer is denoted by X and a resin refractive index of the resin layer is denoted by Y, Equation (1) is satisfied.

X≤−5.43×Y+11.664 (1)

### Aspect 8

A display device including the wiring body according to any one of aspects 1 to 7.

### REFERENCE SIGNS LIST

1 Light transmissive substrate (substrate)
5 Conductor layer
7 First resin layer
8 Second resin layer
9 Resin layer
50 Electroconductive line
100 Display device
200 Wiring body

What is claimed is:

1. A wiring body comprising:
a substrate;
a mesh-like conductor layer provided on the substrate; and
a resin layer covering the conductor layer, wherein
the resin layer includes a first resin layer and a second resin layer in order from the substrate side, and
the conductor layer passes through the first resin layer.

2. The wiring body according to claim 1, wherein the second resin layer has a thickness smaller than a thickness of the first resin layer.

3. The wiring body according to claim 1, wherein the first resin layer and the second resin layer are made of a same resin material.

4. The wiring body according to claim 1, wherein an aspect ratio obtained by dividing a height dimension of an electroconductive line constituting the conductor layer by a width dimension of the electroconductive line is greater than 1.

5. The wiring body according to claim 1, wherein the first resin layer covers side surfaces and a part of an upper surface of an electroconductive line constituting the conductor layer, and
the second resin layer covers the first resin layer and another part of the upper surface of the electroconductive line.

6. The wiring body according to claim 5, wherein an area of the second resin layer covering the upper surface of the electroconductive line is greater than an area of the first resin layer covering the upper surface of the electroconductive line.

7. The wiring body according to claim 1, wherein when a thickness of the second resin layer is denoted by X and a resin refractive index of the resin layer is denoted by Y, Equation (1) is satisfied.
X≤−5.43×Y+11.664 (1)

8. A display device comprising the wiring body according to claim 1.
